(19) United States
(12) Patent Application Publication
(10) Pub. No.: US 2026/0171969 A1
(43) Pub. Date: Jun. 18, 2026

(54) CRYSTAL OSCILLATOR WITH SELF-ADAPTIVE AMPLIFIER CONDUCTION ANGLE CONTROL

(71) Applicant: The Hong Kong University of Science and Technology, Hong Kong (CN)

(72) Inventors: Yihan ZHANG, Hong Kong (CN); Manyu WANG, Hong Kong (CN); Peng WANG, Hong Kong (CN)

(21) Appl. No.: 19/420,758

(22) Filed: Dec. 16, 2025

Related U.S. Application Data
(60) Provisional application No. 63/734,760, filed on Dec. 17, 2024.

(51) Int. Cl. H03B 5/36

(52) U.S. Cl. CPC H03B 5/364; H03B 2200/0082

(57) ABSTRACT

The present invention provides a crystal oscillator using a digitally defined conduction angle that is adaptive to the current oscillation amplitude to operate the crystal oscillator's sustaining amplifier in a Class-C fashion. System-level simulation shows 80% to 90% power efficiency when using a θ-modulated subthreshold inverter. It is also demonstrated that the conduction-angle-adaptive crystal oscillator can reduce the circuit's power consumption at small chip area while preserving an intrinsic start-up capability.

### CROSS-REFERENCE TO RELATED APPLICATIONS:

The present application claims priority from the U.S. Provisional Ser. No. 63/734,760 filed on 17 Dec. 2024, and the disclosure of which is incorporated herein by reference in its entirety.

### FIELD OF THE INVENTION

The present invention generally relates to crystal oscillator technology, and more specifically relates to a crystal oscillator using amplifier with self-adaptive conduction angle control for efficiency boost.

### BACKGROUND OF THE INVENTION

Crystal oscillators are widely used in real-time clocks (RTC) embedded in various electronic systems. Their performance is critical in battery-powered Internet-of-Things (IoT) sensor nodes when serving as wake-up timers. Extending battery life requires an ultra-low-power crystal oscillator, since it must remain always-on. It also requires good frequency stability; otherwise, the system has to extend its communication guard times for synchronization, in which power-hungry transceivers need to stay active, leading to extra waste in power. These demands have motivated much recent research to seek alternatives to the classic inverter-based Pierce oscillator, which is simple in design but typically consumes 10 to 100 nano-Watts (nW) of power.

Typically, a crystal oscillator is constructed by combining an oscillator amplifier and a piezoelectric crystal in a closed feedback loop. To achieve a high power efficiency, the amplifier can be designed to operate in a specific class, which introduces the concept of conduction angle. A conduction angle is defined as the ratio between the time the amplifier is connected to the power supply divided by its period, and the conduction needs to happen around the times when the oscillation waveform is at its peaks or valleys.

One previous invention that uses the concept of conduction angle modulation is the pulse-injection crystal oscillator. They typically work with a tiny conduction angle in the form of short pulses for power reduction. However, this topology has drawbacks. Positioning current injections to the optimum timing typically requires generating an accurate delay, making chip fabrication of pulse generators area-consuming. Moreover, the delay-based timing generation mechanism cannot initiate the oscillation, as the zero-crossing instants, which are the starting times of the delay, are only available once an oscillation is present. These pulse-injection crystal oscillators, hence, need to embed separate start-up circuits to build up the initial oscillation, necessitating extra control logic and facing robustness challenges under accidental but strong interferences. Therefore, a compact and easy-to-use ultra-low-power crystal oscillator remains in demand from the cost-sensitive IoT market.

### SUMMARY OF THE INVENTION

The present invention encloses a crystal oscillator using an amplitude-modulated and digitally defined conduction angle to operate a Pierce inverter in a Class-C fashion to fulfill the need for ultra-low-power and easy-to-use crystal oscillators.

In accordance with one aspect of the present invention, the crystal oscillator comprises: a crystal resonator having a pair of first and second terminals; an oscillation amplifier having an input terminal and an output terminal connected to the first terminal and the second terminal of the crystal resonator respectively; a high-side power-gating switch connected between a first reference terminal of the oscillation amplifier and a first reference voltage; a low-side power-gating switch connected between a second reference terminal of the oscillation amplifier to a second reference voltage; a high-side oscillation amplitude detector having: a first high-side sensing input terminal and a second high-side sensing input terminal connected to the first terminal and the second terminal of the crystal resonator respectively; a high-side driver having a high-side driver input terminal connected to a high-side sensing output terminal of the high-side oscillation amplitude detector; and a high-side driver output terminal connected to a control terminal of the high-side power-gating switch; a low-side oscillation amplitude detector having: a first low-side sensing input terminal and a second low-side sensing input terminal connected to the first terminal and the second terminal of the crystal resonator respectively; and a low-side driver having a low-side driver input terminal connected to a low-side sensing output terminal of the low-side oscillation amplitude detector; and a low-side driver output terminal connected to a control terminal of the low-side power-gating switch.

Preferably, the oscillation amplifier includes: a high-side amplifying transistor having a source connected to the high-side power-gating switch, a drain connected to the second terminal of the crystal resonator, and a gate connected to the first terminal of the crystal resonator; and a low-side amplifying transistor having a source connected to the low-side power-gating switch, a drain connected to the second terminal of the crystal resonator, and a gate connected to the first terminal of the crystal resonator.

Preferably, the high-side amplifying transistor is a PMOS transistor, and the low-side amplifying transistor is an NMOS transistor.

Preferably, the high-side driver includes one or more inverters connected in series between the high-side driver input terminal and the high-side driver output terminal.

Preferably, the low-side driver includes one or more inverters connected in series between the low-side driver input terminal and the low-side driver output terminal.

Preferably, the high-side power-gating switch includes a PMOS transistor having a source connected to the first reference voltage, a drain connected to the oscillation amplifier, and a gate connected to the high-side driver output terminal.

Preferably, the high-side driver includes an even number of inverters connected in series between the high-side driver input terminal and the high-side driver output terminal.

Preferably, the low-side power-gating switch includes a NMOS transistor having a source connected to the second reference voltage, a drain connected to the oscillation amplifier, and a gate connected to the low-side driver output terminal.

Preferably, the low-side driver includes an even number of inverters connected in series between the low-side driver input terminal and the low-side driver output terminal.

Preferably, the high-side power-gating switch includes a NMOS transistor having a drain connected to the first reference voltage, a source connected to the oscillation amplifier, and a gate connected to the high-side driver output terminal.

Preferably, the high-side driver includes an odd number of inverters connected in series between the high-side driver input terminal and the high-side driver output terminal.

Preferably, the low-side power-gating switch includes a PMOS transistor having a drain connected to the second reference voltage, a source connected to the oscillation amplifier, and a gate connected to the low-side driver output terminal.

Preferably, the low-side driver includes an odd number of inverters connected in series between the low-side driver input terminal and the low-side driver output terminal.

Preferably, the high-side oscillation amplitude detector includes: a high-side capacitor having a first terminal connected to the first high-side sensing input terminal and a second terminal connected to the high-side sensing output terminal; a first high-side diode having an anode connected to the second high-side sensing input terminal and a cathode connected to the high-side sensing output terminal; and a second high-side diode having an anode connected to a reference voltage such that the second high-side diode is in a reverse-biased state and a cathode connected to the high-side sensing output terminal.

Preferably, the low-side oscillation amplitude detector includes: a low-side capacitor having a first terminal connected to the first low-side sensing input terminal and a second terminal connected to the low-side sensing output terminal; a first low-side diode having a cathode connected to the second low-side sensing input terminal and an anode connected to the low-side sensing output terminal; and a second low-side diode having a cathode connected to a reference voltage such that the second low-side diode is in a reverse-biased state and an anode connected to the low-side sensing output terminal.

Compared to pulse-injection crystal oscillators, the conduction-angle-adaptive crystal oscillator provided by the present invention saves area and power by using a larger θ to avoid generating accurate delays. System-level simulation shows 80% to 90% power efficiency when using a θ-modulated subthreshold inverter. It is also demonstrated that the conduction-angle-adaptive crystal oscillator can achieve ultra-low power consumption at small chip area while preserving an intrinsic start-up capability.

### BRIEF DESCRIPTION OF THE DRAWINGS

Embodiments of the invention are described in more details hereinafter with reference to the drawings, in which:

FIG. 1 is a circuit block diagram of a crystal oscillator in accordance with one embodiment of the present invention.

FIG. 2 shows a more detailed schematic diagram of the crystal oscillator of FIG. 1.

FIG. 3 illustrates working principle of the self-adaptive conduction angle control of the crystal oscillator.

FIG. 4 shows typical signal waveforms to demonstrate the operating principle of the crystal oscillator.

### DETAILED DESCRIPTION

In the following description, details of the present invention are set forth as preferred embodiments. It will be apparent to those skilled in the art that modifications, including additions and/or substitutions, may be made without departing from the scope and spirit of the invention. Specific details may be omitted so as not to obscure the invention; however, the disclosure is written to enable one skilled in the art to practice the teachings herein without undue experimentation.

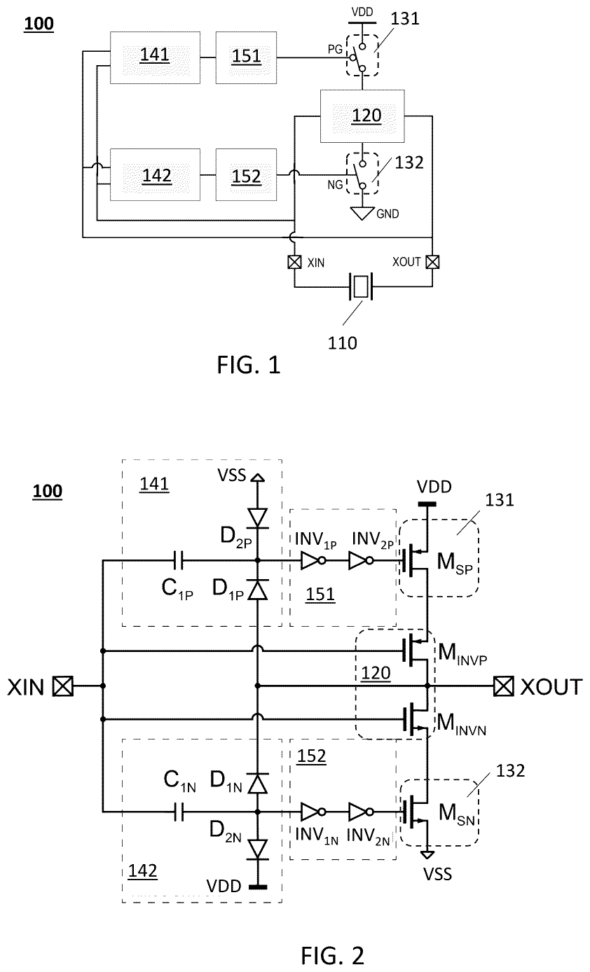

FIG. 1 is a circuit block diagram of a crystal oscillator 100 in accordance with one embodiment of the present invention. As shown, the crystal oscillator 100 comprises a crystal resonator 110 having a pair of terminals XIN and XOUT; and an oscillation amplifier 120 having an input terminal and an output terminal connected to the terminals XIN and XOUT, respectively.

The crystal oscillator 100 further comprises a high-side power-gating switch 131 connecting a first reference terminal of the oscillation amplifier to a reference voltage VDD; and a low-side power-gating switch 132 connecting a second reference terminal of the oscillation amplifier to a reference voltage VSS (e.g., a ground GND).

The crystal oscillator 100 further comprises a high-side oscillation amplitude detector 141 configured to generate conduction information for the high-side power-gating switch 131. The high-side oscillation amplitude detector 141 has a first sensing input terminal and a second sensing input terminal connected to the terminals XIN and XOUT of the crystal resonator 110, respectively.

The crystal oscillator 100 further comprises a high-side driver 151 configured to drive the high-side power-gating switch 131 on or off. The high-side driver 151 has an input terminal connected to a sensing output terminal of the high-side oscillation amplitude detector 141; and an output terminal connected to a control terminal of the high-side power-gating switch 131.

The crystal oscillator 100 further comprises a low-side oscillation amplitude detector 142 configured to generate conduction information for the low-side power-gating switch 132. The low-side oscillation amplitude detector 142 has a first sensing input terminal and a second sensing input terminal connected to the terminals XIN and XOUT of the crystal resonator 110, respectively.

The crystal oscillator 100 further comprises a low-side driver 152 configured to drive the low-side power-gating switch 132 on or off. The low-side driver 152 has an input terminal connected to a sensing output terminal of the low-side oscillation amplitude detector 142; and an output terminal connected to a control terminal of the low-side power-gating switch 132.

FIG. 2 shows a more detailed schematic diagram of the crystal oscillator 100. The oscillation amplifier 120 includes: a high-side amplifying transistor M_{INVP} having a source connected to the high-side power-gating switch 131, a drain connected to the terminal XOUT of the crystal resonator, and a gate connected to the terminal XIN of the crystal resonator. The oscillation amplifier 120 further includes a low-side amplifying transistor M_{INVN} having a source connected to the low-side power-gating switch 132, a drain connected to the terminal XOUT of the crystal resonator, and a gate connected to the terminal XIN of the crystal resonator. Preferably, the high-side amplifying transistor M_{INVP} is a PMOS transistor; and the low-side amplifying transistor M_{INVN} is an NMOS transistor.

The high-side oscillation amplitude detector 142 includes: a high-side capacitor C_{1P} having a first terminal connected to the first high-side sensing input terminal and a second terminal connected to the high-side sensing output terminal; a first high-side diode D_{1P} having an anode connected to the second high-side sensing input terminal and a cathode connected to the high-side sensing output terminal; and a second high-side diode D_{2P} having an anode connected to the reference voltage VSS and a cathode connected to the high-side sensing output terminal.

The low-side oscillation amplitude detector 142 includes: a low-side capacitor C_{1N} having a first terminal connected to the first low-side sensing input terminal and a second terminal connected to the low-side sensing output terminal; a first low-side diode D_{1N} having a cathode connected to the second low-side sensing input terminal and an anode connected to the low-side sensing output terminal; and a second low-side diode D_{2N} having a cathode connected to the reference voltage VDD and an anode connected to the low-side sensing output terminal.

The high-side driver 151 includes an inverter chain with one or more inverters connected in series from the high-side driver input terminal to the high-side driver output terminal. The low-side driver 152 includes an inverter chain with one or more inverters connected in series from the low-side driver input terminal and the low-side driver output terminal.

In the embodiment as shown in FIG. 2, the high-side power-gating switch 131 includes a PMOS transistor M_{SP} having a source connected to the reference voltage VDD, a drain connected to the oscillation amplifier 120, and a gate connected to the output terminal of the high-side driver 151; and the high-side driver 151 includes an even number of inverters connected in series between the high-side driver input terminal and the high-side driver output terminal.

The low-side power-gating switch 132 includes a NMOS transistor M_{SN} having a source connected to the reference voltage VSS, a drain connected to the oscillation amplifier 120, and a gate connected to the output terminal of the low-side driver 152; and the low-side driver 152 includes an even number of inverters connected in series between the low-side driver input terminal and the low-side driver output terminal.

Alternatively, the high-side power-gating switch 131 may include a NMOS transistor M_{SN} having a drain connected to the reference voltage VDD, a source connected to the oscillation amplifier 120, and a gate connected to the output terminal of the high-side driver 151; and the high-side driver 151 includes an odd number of inverters connected in series between the high-side driver input terminal and the high-side driver output terminal.

The low-side power-gating switch 132 may include a PMOS transistor M_{SP} having a drain connected to the reference voltage VSS, a source connected to the oscillation amplifier 120, and a gate connected to the output terminal of the low-side driver 152; and the low-side driver 152 includes an odd number of inverters connected in series between the low-side driver input terminal and the low-side driver output terminal.

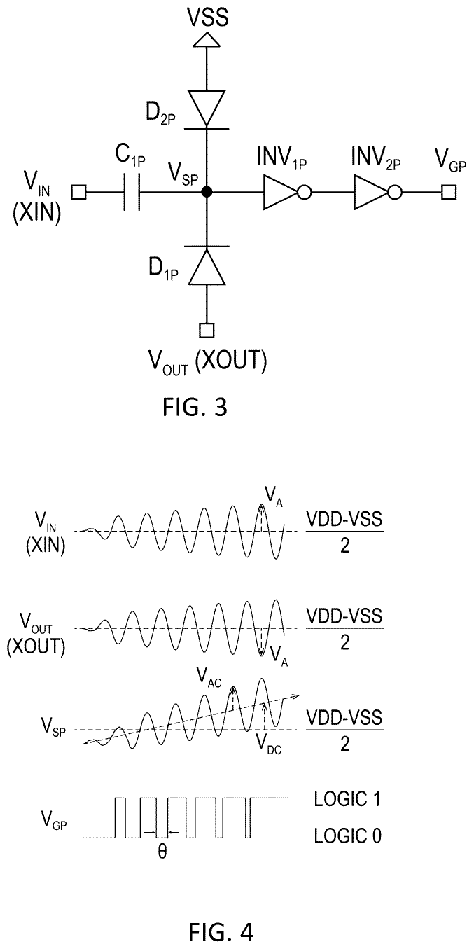

FIG. 3 illustrates the working principle of the high-side amplitude detector 141. As the oscillation amplitude increases, the amplitude detector senses this amplitude information and generates corresponding control signals to the switch drivers to operate the power-gating switches. Before the oscillation amplitude reaches a certain threshold, the conduction angle is 360°, indicating that the oscillator amplifier is constantly connected to VDD and VSS, to ensure proper oscillation initialization, like the Pierce oscillator.

More specifically, the high-side amplitude detector 141 is configured to produce a decrease in the conduction angle θ by level-shifting the voltage V_{IN} at XIN with an amplitude-dependent V_{DC}, which stays negative when the voltage amplitude of the oscillation V_{A} is low but increases rapidly as it grows. Hence, before the voltage amplitude V_{A} reaches a threshold V_{A,TH}, the conduction angle θ stays at 360°. When V_{A} grows beyond V_{A,TH}, the output of the amplitude detector sees an increasing fraction of the waveform being higher than the threshold voltage of the inverter INV_{1P}, since C_{1P} and D_{1P} form a charge pump, with XIN and XOUT being the two inputs.

At steady state, C_{1P} stores a 2V_{A}-V_{D} (V_{D} being the forward voltage of D_{1P}) DC voltage difference from V_{IN} to the amplitude detector's output, as V_{IN} and V_{OUT} are 180°-out-of-phase from parallel oscillation. The AC component of V_{IN} couples directly to the amplitude detector's output. Hence, the charge pump formed of C_{1P} and D_{1P} ideally creates an AC-to-DC gain of 2 and an AC-to-AC gain of 1. Diode D_{2P} is connected between the output of the amplitude detector and V_{SS} under reverse bias to create a negative DC voltage shift, which is the source of V_{A,TH}. In one embodiment, D_{2P} is implemented as multiple D_{1P}S connected in parallel (e.g., D_{2P}=5×D_{1P}). This allows the voltage of the amplitude detector's output rely only on the shape of the diodes' I-V characteristics when V_{A} is 0.

The overall structure of the high-side amplitude detector 141 produces a waveform that is always lower than the threshold voltage of INV_{1P} when no oscillation is present (i.e., θ=360°). As the oscillation amplitudes (V_{IN} at XIN and V_{OUT} at XOUT) increase, the duration of output voltage (V_{SP}) of the amplitude detector 141 lower than the threshold voltage of INV_{1P} reduces. Referring to FIG. 4, such waveform of V_{SP}, processed by the high-side switch driver 151, creates a control signal (V_{GP}) at the gate of the high-side power-gating transistor M_{SP}, whose frequency is identical to the crystal resonator's fundamental frequency, but with a decreasing duty cycle (the time duration of the closed state of the power-gating switch divided by the period of the clock signal) as the oscillation amplitude grows. This effectively creates a decreasing conduction angle through M_{SP} to only connect the oscillator amplifier (in this case, a Pierce oscillator) to the supply voltage at times when energy efficiency is high.

The low-side oscillation amplitude detector 142 works in a similar fashion to create a voltage with a decreasing fraction of its waveform being higher than the inverter threshold voltage as the oscillation amplitude grows. This further produces a control signal (V_{GN}) with decreasing duty cycle at the gate of M_{SN} as the oscillation amplitude increases. Hence, the present circuit topology creates a decreasing conduction angle through M_{SN} to only connect the oscillation amplifier to the reference voltage VSS at times when energy efficiency is high.

Therefore, the oscillating circuit provided by the present invention keeps a maximum conduction angle before the oscillator amplifier initiates the oscillation and self-adjust the conduction angle by reducing the conduction angle in accordance with the current oscillation amplitude.

Comparing with previously published ultra-low-power crystal oscillators, the present invention has a robust efficiency boost across a wide range of θ, lower power consumption and simpler design. In addition, its intrinsic start-up capability provided by amplitude-based regulation is unique among ultra-low-power crystal oscillators operating in the sub-nW power regime. These features make the present invention a competitive choice for future RTC applications in IoT sensor nodes: its record-low power extends the system's battery life, its tiny area leads to low manufacturing cost, and its single-supply nature with intrinsic start-up capability makes it easy to use, holding the promise to serve as a pin-to-pin replacement of the classic Pierce oscillator.

The functional units and modules in accordance with the embodiments disclosed herein may be implemented using computing devices, computer processors, or electronic circuitries including but not limited to analog electronic devices/modules, application specific integrated circuits (ASIC), field programmable gate arrays (FPGA), microcontrollers, and other programmable logic devices configured or programmed according to the teachings of the present disclosure. Computer instructions or software codes running in the computing devices, computer processors, or programmable logic devices can readily be prepared by practitioners skilled in the software or electronic art based on the teachings of the present disclosure.

All or portions of the methods in accordance with the embodiments may be executed in one or more computing devices, including server computers, personal computers, laptop computers, mobile computing devices such as smartphones, and tablet computers.

The embodiments may include computer storage media, transient and non-transient memory devices having computer instructions or software codes stored therein, which can be used to program or configure the computing devices, computer processors, or electronic circuitries to perform any of the processes of the present invention. The storage media, transient and non-transient memory devices can include, but are not limited to, floppy disks, optical discs, Blu-ray Disc, DVD, CD-ROMs, and magneto-optical disks, ROMs, RAMs, flash memory devices, or any type of media or devices suitable for storing instructions, codes, and/or data.

Each of the functional units and modules in accordance with various embodiments also may be implemented in distributed computing environments and/or Cloud computing environments, wherein the whole or portions of machine instructions are executed in distributed fashion by one or more processing devices interconnected by a communication network, such as an intranet, Wide Area Network (WAN), Local Area Network (LAN), the Internet, and other forms of data transmission medium.

While the present disclosure has been described and illustrated with reference to specific embodiments thereof, these descriptions and illustrations are not limiting. The illustrations may not necessarily be drawn to scale. There may be distinctions between the illustrations in the present disclosure and the actual apparatus due to manufacturing processes and tolerances. There may be other embodiments of the present disclosure which are not specifically illustrated. Modifications may be made to adapt a particular situation, material, composition of matter, method, or process to the objective and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations.

What is claimed is:

1. A crystal oscillator with self-adaptive amplifier conduction angle control, comprising:
a crystal resonator having a pair of first and second terminals;
an oscillation amplifier having an input terminal and an output terminal connected to the first terminal and the second terminal of the crystal resonator, respectively;
a high-side power-gating switch connected between a first reference terminal of the oscillation amplifier and a first reference voltage;
a low-side power-gating switch connected between a second reference terminal of the oscillation amplifier to a second reference voltage;
a high-side oscillation amplitude detector having: a first high-side sensing input terminal and a second high-side sensing input terminal connected to the first terminal and the second terminal of the crystal resonator, respectively;
a high-side driver having a high-side driver input terminal connected to a high-side sensing output terminal of the high-side oscillation amplitude detector; and a high-side driver output terminal connected to a control terminal of the high-side power-gating switch;
a low-side oscillation amplitude detector having: a first low-side sensing input terminal and a second low-side sensing input terminal connected to the first terminal and the second terminal of the crystal resonator, respectively; and a low-side driver having a low-side driver input terminal connected to a low-side sensing output terminal of the low-side oscillation amplitude detector; and a low-side driver output terminal connected to a control terminal of the low-side power-gating switch.

2. The crystal oscillator of claim 1, wherein the oscillation amplifier includes:
a high-side amplifying transistor having a source connected to the high-side power-gating switch, a drain connected to the second terminal of the crystal resonator, and a gate connected to the first terminal of the crystal resonator; and
a low-side amplifying transistor having a source connected to the low-side power-gating switch, a drain connected to the second terminal of the crystal resonator, and a gate connected to the first terminal of the crystal resonator.

3. The crystal oscillator of claim 2, wherein the high-side amplifying transistor is a PMOS transistor; and the low-side amplifying transistor is an NMOS transistor.

4. The crystal oscillator of claim 1, wherein the high-side driver includes one or more inverters connected in series between the high-side driver input terminal and the high-side driver output terminal.

5. The crystal oscillator of claim 1, wherein the low-side driver includes one or more inverters connected in series between the low-side driver input terminal and the low-side driver output terminal.

6. The crystal oscillator of claim 1, wherein the high-side power-gating switch includes a PMOS transistor having a source connected to the first reference voltage, a drain connected to the oscillation amplifier, and a gate connected to the high-side driver output terminal.

7. The crystal oscillator of claim 4, wherein the high-side driver includes an even number of inverters connected in series between the high-side driver input terminal and the high-side driver output terminal.

8. The crystal oscillator of claim 1, wherein the low-side power-gating switch includes a NMOS transistor having a source connected to the second reference voltage, a drain connected to the oscillation amplifier, and a gate connected to the low-side driver output terminal.

9. The crystal oscillator of claim 8, wherein the low-side driver includes an even number of inverters connected in series between the low-side driver input terminal and the low-side driver output terminal.

10. The crystal oscillator of claim 1, wherein the high-side power-gating switch includes a NMOS transistor having a drain connected to the first reference voltage, a source connected to the oscillation amplifier, and a gate connected to the high-side driver output terminal.

11. The crystal oscillator of claim 10, wherein the high-side driver includes an odd number of inverters connected in series between the high-side driver input terminal and the high-side driver output terminal.

12. The crystal oscillator of claim 1, wherein the low-side power-gating switch includes a PMOS transistor having a drain connected to the second reference voltage, a source connected to the oscillation amplifier, and a gate connected to the low-side driver output terminal.

13. The crystal oscillator of claim 12, wherein the low-side driver includes an odd number of inverters connected in series between the low-side driver input terminal and the low-side driver output terminal.

14. The crystal oscillator of claim 1, wherein the high-side oscillation amplitude detector includes:
a high-side capacitor having a first terminal connected to the first high-side sensing input terminal and a second terminal connected to the high-side sensing output terminal;
a first high-side diode having an anode connected to the second high-side sensing input terminal and a cathode connected to the high-side sensing output terminal; and
a second high-side diode having an anode connected to a reference voltage such that the second high-side diode is in a reverse-biased state, and a cathode connected to the high-side sensing output terminal.

15. The crystal oscillator of claim 1, wherein the low-side oscillation amplitude detector includes:
a low-side capacitor having a first terminal connected to the first low-side sensing input terminal and a second terminal connected to the low-side sensing output terminal;
a first low-side diode having a cathode connected to the second low-side sensing input terminal and an anode connected to the low-side sensing output terminal; and
a second low-side diode having a cathode connected to a reference voltage such that the second low-side diode is in a reverse-biased state and an anode connected to the low-side sensing output terminal.
